(19) United States
(12) Patent Application Publication
(10) Pub. No.: US 2019/0107593 A1
(43) Pub. Date: Apr. 11, 2019

(54) MAGNETIC RESONANCE METHODOLOGY FOR IMAGING OF EXCHANGE-RELAYED INTRAMOLECULAR NUCLEAR OVERHAUSER ENHANCEMENT EFFECTS IN MOBILE SOLUTES

(71) Applicants: THE JOHNS HOPKINS UNIVERSITY, Baltimore, MD (US); KENNEDY KRIEGER INSTITUTE, INC., Baltimore, MD (US)

(72) Inventors: Peter C. van Zijl, Ellicott City, MD (US); Craig K. Jones, Owings Mills, MD (US)

(21) Appl. No.: 15/944,237

(22) Filed: Apr. 3, 2018

Related U.S. Application Data
(63) Continuation of application No. 13/447,337, filed on Apr. 16, 2012, now abandoned.
(60) Provisional application No. 61/476,016, filed on Apr. 15, 2011.

(51) Int. Cl. G01R 33/56

(52) U.S. Cl. CPC G01R 33/5601; G01R 33/4838; G01R 33/5605

(57) ABSTRACT

An embodiment in accordance with the present invention provides a method for imaging exchange-relayed intramolecular Nuclear Overhauser Enhancement (NOE) effects with Magnetic Resonance (MR) in mobile solutes. In the method, non-exchangeable protons or other magnetic nuclei with resonances of a finite linewidth in the NMR proton spectrum within a species or subject can be labeled magnetically using radiofrequency. Intramolecular NOE effects can then transfer the label between the non-exchangeable nuclei and non-exchangeable and exchangeable protons in the same molecule during a magnetic steady state. The water signal is monitored to observe a reduction in the water signal due to the transfer of NOE labels to the water signal in a manner relayed through the exchangeable protons. Analysis can also be performed to produce an image or spectrum of the subject.

### CROSS REFERENCE TO RELATED APPLICATIONS

This application is a Continuation of U.S. patent application Ser. No. 13/447,337, filed Apr. 16, 2012, which claims the benefit of U.S. Provisional Patent Application No. 61/476,016 filed Apr. 15, 2011, the content of each of the aforementioned applications is herein incorporated by reference in their entirety.

### GOVERNMENT SUPPORT

This invention was made with government support under grant numbers RR015241 and EB015909, awarded by the National Institutes of Health. The government has certain rights in the invention.

### FIELD OF THE INVENTION

The present invention relates generally to medical imaging. More particularly, the present invention relates to a method of magnetic resonance imaging.

### BACKGROUND OF THE INVENTION

Magnetic resonance imaging (MRI) has long been used to create detailed internal images for use in medical diagnostics and treatment as well as studies of the brain and body. In MRI, a powerful magnetic field is used to align the magnetization of atomic nuclei in the body, and radio frequency is used to alter the alignment of the magnetization. The nuclei then produce a rotating magnetic field that is detectable by an MRI scanner and recordable to create images of the scanned area of the body. Over the years, various techniques have been developed to perform MRI scans that produce images for specialized diagnostics.

One type of MRI scan is known as magnetization transfer contrast (MTC) MRI. With regards to imaging technology, MTC refers to the transfer of magnetization from protons in semi-solid and solid-like motional environments to the water protons. In MRI one can approximately distinguish two broad classes of molecules based on their motional and relaxation properties, mobile and semi-solid/solid molecules. Mobile molecules have a faster average rotational frequency and therefore their protons experience reduced coupling to surrounding protons and thus reduced transverse relaxation (extreme narrowing regime). Because of this, most protons in mobile molecules have a narrow Lorentzian resonance lineshape visible in the normal proton MR spectrum in a bandwidth of about 10 ppm around the water proton resonance frequency. This phenomenon is known as “motional averaging” or extreme narrowing and is characteristic of protons in mobile molecules. In contrast, semi-solid and solid molecules have very slow rotational frequency and protons in such an environment are relaxed strongly by dipolar coupling with neighboring protons and though chemical shielding anisotropy leading to resonances of tens of kHz (hundreds or even thousands of ppm) wide and not visible in the normal proton spectrum.

Exchange mechanisms, such as through-space dipolar coupling or proton chemical exchange (physical exchange of protons such as OH, NH or SH protons) between molecules allow the protons in both mobile and semi-solid/solid macromolecules to interact with the bulk (solvent) media and establish a dynamic equilibrium.

The MTC methodology detects magnetization transfer from the MR-invisible semi-solid/solid protons to the bulk water via these processes. While there is no measurable signal from the semi-solid spins due to the very short T2 (order of microseconds), the longitudinal magnetization is better preserved and after excitation of the proton spin system recovery via T₁ relaxation is relatively slow. The longitudinal magnetization of the semi-solid/solid spins can be selectively altered and transferred between the protons in the semi-solid/solid, and, in turn, this alteration can be measured in the spins of the bulk media, due to the exchange processes. The conventional MTC sequence applies an RF saturation (either continuous or pulsed) at a frequency that is off-resonance for the narrow line of bulk water but still on resonance for the bound protons with a spectral linewidth in the range of tens to hundreds of kHz. This causes saturation of the bound spins and transfer of this saturation within this semi-solid/solid environment via fast spin-diffusion, an intramolecular through-space dipolar coupling phenomenon. This saturation can subsequently exchange into the bulk water either through (i) through-space dipolar coupling with bound water or (ii) physical exchange of protons in OH, NH, NH₂ and SH groups, resulting in a loss of longitudinal magnetization and hence signal decrease in the bulk water. Because of the slow motional state of the water bound to the semi-solid, it is generally assumed that mechanism (i) is a main contributor. The magnetization transfer provides an indirect measure of semisolid/solid macromolecular content in tissue. Implementation of MTC therefore involves choosing suitable frequency offsets and pulse shapes to saturate the semi-solid/solid spins sufficiently specific, i.e. without affecting mobile systems in the normal proton spectrum.

The spin-diffusion in semi-solid/solid systems is one example of intramolecular nuclear overhauser enhancement (NOE) effects. Intramolecular NOEs are a type of through-space dipolar, cross-relaxation that can occur between nuclei that are in spatial proximity. Their magnitude and detectability depend on the distance between the nuclei (effect proportional to 1/r⁶, with r being the distance between protons) as well as on the molecular tumbling rate (motional range). They can occur between nuclei with a magnetic moment (e.g. 1H, 13C, 31P, 15N, 19F, etc.) both homonuclear, e.g. 1H-1H and heteronuclear, e.g. 1H-13C. They happen extremely fast in semi-solid/solid systems and slower in mobile macromolecules.

NOE effects have been studied in high-resolution NMR spectroscopy in solution (in vitro) for several decades and are used there to assess molecular structure, molecular dynamics and molecular binding. The 2002 Nobel Prize in Chemistry was given to Kurt Wüthrich for the use of intramolecular NOEs in multidimensional spectroscopy for the determination of macromolecular structure. Fast intramolecular NOE effects (also called spin diffusion) occur within semi-solids or solid components of tissue and have been used in conventional magnetization transfer contrast (MTC). In MTC such solid and/or semi-solid compounds can be excited in a resonance range separate from solvent water because of a very short T₂ on the order of microseconds. In MTC, after this off resonance excitation, the magnetization is transferred to the water in large part using through-space intermolecular transfer to bound water.

While conventional methods of MTC observation of NOE effects are quite useful, these known methods are used only to study semi-solid and/or solid compounds or tissue constituents that have characteristically short T₂s in the microsecond range. It would therefore be advantageous to have a method for water-based observation of NOE effects between non-exchangeable protons with a long T₂ in mobile solutes, including for macromolecules such as proteins and peptides as well as for small molecules.

It is also well known from basic NMR that NOE (dipolar cross relaxation) and chemical exchange (CE) are possible types of magnetization transfer (MT) pathways that may contribute to saturation transfer experiments. Their pathways are active together in most MT experiments and difficult to separate completely. The relative contributions of these pathways may vary with the type of excitation scheme used and depend on the molecular mobility and conformation, which will affect dipolar transfer efficiency and water accessibility, respectively.

It would therefore be advantageous to provide a method of MRI that images exchange relayed intramolecular nuclear overhauser enhancement effects in mobile solutes generated by the saturation of non-exchangeable protons, the transfer of the signal to exchangeable protons, and subsequent transfer of the signal to water, such that the contrast is visible on the water, while the effects of conventional MTC are very small.

### SUMMARY OF THE INVENTION

The foregoing needs are met, to a great extent, by the present invention, wherein in one aspect, a method for obtaining a magnetic resonance imaging (MRI) image, includes performing a magnetic labeling MRI experiment on non-exchangeable protons of molecules with resonances of finite linewidth in the NMR proton spectrum. The method also includes waiting for intramolecular nuclear overhauser enhancement (NOE) effects to occur between the non-exchangeable protons types and non-exchangeable and exchangeable protons in the same molecule during a magnetic steady state and monitoring a reduction in a water signal due to a transfer of NOE labels to the water signal in a manner relayed through the exchangeable protons. Additionally, the method can include performing analysis to produce an image of the subject.

In accordance with another aspect of the present invention the non-exchangeable protons can take the form of one or more of the group of aliphatic, olefinic, and aromatic protons. These non-exchangeable protons can be endogenous or exogenous molecules and have a transverse relaxation time T₂ in the millisecond range due to the mobile properties of the molecule, which makes them resonate in the boundaries of the normal proton spectrum about ±10 ppm around the water proton resonance. The step of performing magnetic labeling can also include selectively irradiating and saturating one or more of the non-exchangeable protons for a particular compound over a predetermined frequency range, as well as, selectively exciting one or more protons of the non-exchangeable protons for a particular compound over the predetermined frequency range. Selectively exciting the protons can further include pulsed radiofrequency (RF) inversion using one or more RF pulses, and selectively irradiating and saturating further includes inducing a magnetic steady state such that intramolecular NOEs occur in mobile solute molecules.

In accordance with another aspect of the present invention, the endogenous molecules can include one or more of the group of: tissue molecules containing non-exchangeable aliphatic, olefinic or aromatic protons as well as exchangeable protons, and wherein the endogenous molecules are in the appropriate motional range to allow intramolecular NOEs to occur between non-exchangeable protons and between non-exchangeable and exchangeable protons during the steady state. Tissue molecules can include at least one of the group of proteins, peptides, sugars, metabolites. The contrast agent can include at least one of the group of proteins, peptides, sugars, small organic compounds, small inorganic compounds, organic polymers, inorganic polymers, inorganic complexes, and other mobile species that can be administered in vivo. Notice that when inorganic complexes contain paramagnetic shift metals, the range of the mobile proton resonances may be outside of the normal proton spectrum of 0-10 ppm and cover a large range over which we can excite the non-exchangeable protons and induce NOEs.

In accordance with still another aspect of the present invention, the contrast agent can be configured to be in a predetermined mobility range to display exchange-relayed NOE effects for one of the proton ensembles in vivo or in vitro. Mobility of the contrast agent can be reduced by binding the agent or entering a more viscous environment, which may allow our method to be used to study molecular binding or binding-based reactions in vivo or in vitro.

In accordance with yet another aspect of the present invention, the method can further include using a pulsed steady state MRI sequence containing a short saturation labeling RF pulse followed by a small flip angle excitation pulse and brief spatial encoding of one or more spatial frequencies to selectively irradiate and saturate one or more protons and waiting for NOEs to occur is accomplished frequencies. The method can also further include choosing the pulse sequence parameters to sufficiently reduce the simultaneously occurring effects of MTC contrast to allow visualization of the exchange-relayed NOE contrast. Additionally the method can include monitoring of the water reduction over a predetermined range of frequencies to allow depiction of a direct water saturation. Further, the monitoring of the water reduction can be used to allow a determination of the water frequency shifts on a voxel by voxel basis.

In accordance with another aspect of the present invention, one possible step of performing analysis further includes fitting of a frequency-dependent direct water saturation with a Lorentzian lineshape and subtracting this from the frequency dependent total saturation spectrum to determine an exchange-relayed NOE effect. The step of performing analysis further includes monitoring a water saturation at an appropriate frequency for the protons. Additionally, multiple contrast agents with different types of protons, such as aliphatic, olefinic, and aromatic protons, or single agents containing such multiple proton types can be used to have multiple proton frequencies. An exchange-relayed NOE water signal intensity can be used to monitor pH based on changes in exchange rate with pH, and an effect on the water signal of the contrast agents to monitor concentration of the agent. In accordance with yet another aspect of the present invention, an image produced as a result of the method can take the form of a one-dimensional, two-dimensional or three-dimensional image. Alternatively a spectrum can be acquired without spatial encoding.

In accordance with still another aspect of the present invention, a method for obtaining a magnetic resonance image (MRI) of a subject can include performing a magnetic labeling MRI experiment on non-exchangeable magnetic nuclei with resonances of a finite line width and waiting for an intramolecular nuclear overhauser enhancement (NOE) effect to occur between the non-exchangeable magnetic nuclei and the non-exchangeable and exchangeable magnetic nuclei in the same molecule during a magnetic steady state. The method of labeling can include a single RF pulse or a combination of RF pulses selectively exciting the mentioned non-exchangeable protons and generating non-equilibrium longitudinal magnetization. The method also includes monitoring a reduction in the water signal or a modulation in the water signal due to the transfer of NOE labels to the water signal in an exchange-relayed manner. Additionally, the method includes acquiring the data to produce an image or spectrum of the subject and subsequently analyzing this data.

In accordance with an aspect of the present invention, the magnetic nuclei can take the form of at least one of the group of 1H, 15N, 13C, 31P, 17O, 23Na. The magnetic nuclei can further include any magnetic nuclei identified in the periodic table.

In accordance with yet another aspect of the present invention, a system for providing a magnetic resonance image of a subject in an examination region during a magnetic resonance imaging session includes a magnet configured to generate a magnetic field in the examination region and a gradient coil that superimposes a magnetic field gradient on the magnetic field. The system also includes an RF coil configured to introduce RF pulses to the examination region to magnetically label non-exchangeable magnetic nuclei with resonances of a finite line width in the sample such that an intramolecular nuclear overhauser enhancement (NOE) effect occurs between the non-exchangeable magnetic nuclei and non-exchangeable and exchangeable magnetic nuclei in the same molecule during a magnetic steady state followed by a magnetization transfer through chemical exchange. Additionally, the system includes a scan controller which controls the gradient coil and the RF coil to perform the magnetic resonance imaging session and a receiver configured to receive magnetic resonance signals during the magnetic resonance imaging session. A processor configured to receive data from the receiver is also used, such that the processor is further programmed to convert the magnetic resonance signals into the magnetic resonance image.

### BRIEF DESCRIPTION OF THE DRAWINGS

The accompanying drawings provide visual representations which will be used to more fully describe the representative embodiments disclosed herein and can be used by those skilled in the art to better understand them and their inherent advantages. In these drawings, like reference numerals identify corresponding elements and:

FIG. 1 illustrates a diagram of a method of performing an MR experiment on non-exchangeable protons in accordance with an aspect of the present invention.

FIG. 2 illustrates a diagram of a method of performing an MR experiment on non-exchangeable magnetic nuclei in accordance with an aspect of the present invention.

FIG. 3 illustrates a schematic diagram of a system for performing an MRI experiment in accordance with an aspect of the present invention.

FIG. 4 illustrates the magnetization transfer mechanisms that are active after inversion labeling of water in a water exchange experiment.

FIG. 5 illustrates the time scales of spectral signal build-up in cancer cells for exchangeable amide protons around 8.3 ppm and in the 5-9 ppm range in the proton spectrum in comparison to the build-up of slower intramolecular NOEs, especially in the range of 0-4.5 ppm where the non-exchangeable protons resonate, in accordance with an aspect of the present invention.

FIG. 6 illustrates the time scales of spectral signal build-up in cancer cells for exchangeable amide protons around 8.3 ppm and in the 5-9 ppm range in the proton spectrum in comparison to the build-up of slower intramolecular NOEs, especially in the range of 0-4.5 ppm where the non-exchangeable protons resonate, in accordance with an aspect of the present invention.

FIG. 7 illustrates the possible magnetization transfer mechanisms occurring between magnetic nuclei in a semisolid/solid matrix (indicated in gray) and protons bound to the matrix when performing a MTC-MRI experiment.

FIG. 8 illustrates the principles of chemical exchange saturation transfer (CEST) imaging in which exchangeable protons are directly saturated using radiofrequency (RF) irradiation and their signal loss monitored through the water signal after exchange (k_{sw}) between solute (s) and water (w) protons.

FIG. 9 illustrates the of chemical exchange saturation transfer (CEST) imaging in which exchangeable protons are directly saturated and their signal loss monitored through the water signal.

FIG. 10 illustrates a theoretical Z-spectrum acquired by saturating as a function of frequency and looking at the water signal intensity. Note the change in convention of the ppm scale which now has water at 0 ppm. It is illustrated for the example of chemical exchange saturation transfer (CEST) at 3.5 ppm and direct water saturation at 0 ppm.

FIG. 11 illustrates the principles of asymmetry analysis of CEST data.

FIG. 12 illustrates the dominant MTC effects occurring in in vivo Z-spectra for a brain tumor model (9L glioma, post-implementation day 12, n=6). Using a small coil, saturation power was 1.3 μT and length 4 sec. There is a clear overall reduction of signal to about 60-70% due to MTC.

FIG. 13 illustrates an approach to visualize in vivo CEST effect, such as amide proton transfer (APT) effects, by performing an asymmetry analysis with respect to the water frequency. The difference maximizes at 3.5 ppm from water (arrow).

FIG. 14 illustrates dominant MTC effects occurring in in vivo Z-spectra in the human brain when using continuous RF irradiation used in CEST and MTC experiments (here: saturation time of 4×200 ms and B1=2 μT and TR=2.5 s). There is a clear overall reduction of signal to about 50-60% due to MTC.

FIG. 15 illustrates an approach to visualize in vivo CEST effects in humans, such as amide proton transfer (APT) effects, by performing an asymmetry analysis with respect to the water frequency. The issue with such analysis is that both CEST and exchange-relayed NOEs may contribute as well as potential asymmetries in MTC.

FIG. 16 illustrates an example of a 3D steady state acquisition that can be used to detect exchange-relayed NOE effects and CEST effects while minimizing MTC interference in accordance with an aspect of the present invention.

FIG. 17 illustrates an in in vivo Z-spectrum in the human brain when performing a steady state MRI experiment in accordance with an aspect of the present invention in which CEST and ER-NOE effects are visible while MTC effects are minimal to negligible.

FIG. 18 illustrates CEST and ER-NOE effects fitted out from an in in vivo Z-spectrum in the human brain using Lorentzian difference analysis in accordance with an aspect of the present invention.

FIG. 19 illustrates the Z-spectrum result from a steady-state acquisition in vivo in human brain at 7 Tesla from a method of performing an MRI experiment in accordance with an aspect of the present invention. The Lorentzian analysis employing spectral points at frequencies highlighted by solid dots is also indicated.

FIG. 20 illustrates a graph resultant from Lorentzian difference analysis for a method of performing an MRI experiment in accordance with an aspect of the present invention to allow visualization of the APT effects around 3.5 ppm from water and exchange-relayed NOE effects at negative offsets from water.

FIG. 21 shows exchange-relayed NOE images (primary one −2 to −5 ppm) of the human brain at 7 Tesla from a method of performing an MRI experiment in accordance with an aspect of the present invention.

FIG. 22 illustrates exchange-relayed NOE images obtained on a brain tumor patient resultant from a method of performing an MRI experiment in accordance with an aspect of the present invention

FIG. 23 illustrates exchange-relayed NOE images as compared to diffusion and FLAIR images obtained on a stroke patient resultant from a method of performing an MRI experiment in accordance with an aspect of the present invention.

FIG. 24 illustrates exchange-relayed NOE images obtained on a multiple sclerosis patient as compared to a healthy control resultant from a method of performing an MRI experiment in accordance with an aspect of the present invention.

### DETAILED DESCRIPTION

The presently disclosed subject matter now will be described more fully hereinafter with reference to the accompanying Drawings, in which some, but not all embodiments of the inventions are shown. Like numbers refer to like elements throughout. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated Drawings. Therefore, it is to be understood that the presently disclosed subject matter is not to be limited to the specific embodiments disclosed and that modifications and other embodiments are intended to be included within the scope of the appended claims.

An embodiment in accordance with the present invention provides a method for imaging exchange-relayed intramolecular Nuclear Overhauser Enhancement (NOE) effects with MRI in mobile solutes. In the method, non-exchangeable protons with resonances of a finite linewidth in the NMR proton spectrum are magnetically labeled within a subject. Intramolecular NOE effects can then transfer the label between the non-exchangeable protons and non-exchangeable and exchangeable protons in the same molecule during a magnetic steady state. The water signal is monitored to observe a reduction or modulation in the water signal due to the transfer of NOE labels to the water signal in a manner relayed through the exchangeable protons. Analysis can be performed to produce an image or a spectrum of the subject.

More particularly, the non-exchangeable protons can take the form of aliphatic (alkyl), olefinic (alkene) or aromatic protons with resonances of finite linewidth in the NMR proton spectrum. Alternately, the protons can include any non-exchangeable proton with a sufficiently long transverse relaxation time, T₂, on the order of milliseconds in mobile molecules. These protons can be endogenous compounds in the cell, interstitial space or body fluids such as proteins, peptides, carbohydrates, or smaller metabolites. Additionally, exogenously applied molecules can be used such as diamagnetic or paramagnetic contrast agents taken up in the body. Preferably, the labeled protons will not include the semisolid or solid compounds or tissue constituents studied with conventional magnetization transfer contrast (MTC) that have characteristically short T₂s in the microsecond range and broadened resonances in the proton spectrum that extend well beyond the usual proton spectral range of about 0-12 ppm, with water being around 4.7 ppm. Notice that paramagnetic solutes may have shifted non-exchangeable resonances of finite linewidth and that the magnetic labeling of such resonances is also included in the present invention.

The intramolecular NOEs sought in the present method can be detected for molecules in solution through magnetic labeling (saturation or excitation) of non-exchangeable protons with T₂s in the millisecond range and resonances of finite linewidth in a range of about 10 ppm around the water resonance for diamagnetic compounds and outside this range for paramagnetic compounds. The magnetic labeling is then transferred to the water signal for imaging through exchange-relayed NOE transfer. Generally, in conventional methods for chemical exchange saturation transfer (CEST) MRI, exchangeable protons are directly saturated using radiofrequency and transferred to water immediately through physical (chemical) exchange without through-space dipolar transfer. In MTC experiments, protons with very short T₂s (low microsecond range) are excited and NOEs are transferred mostly directly through space to bound water molecules (intermolecular NOE transfer). In contrast, the pulse sequence of the present invention is focused on mobile species where intermolecular NOEs are negligibly small compared to exchange-relayed intramolecular NOE effects. In addition, the pulse sequence is designed to also minimize NOEs between solid and semi-solid tissue components and water. While CEST effects are also retained, these effects occur in a different frequency range in the MR spectrum. Therefore, their interference is not an issue.

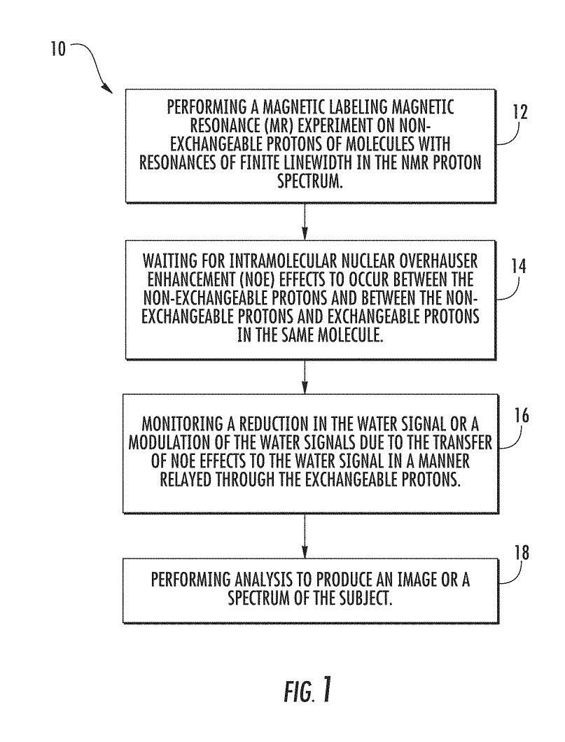

FIG. 1 illustrates a diagram of a method in accordance with an embodiment of the invention. More particularly, FIG. 1 illustrates a method 10 of obtaining a magnetic resonance imaging (MRI) image including a step 12 of performing a magnetic labeling MRI experiment on non-exchangeable protons of endogenous or exogenous molecules with resonances of a finite linewidth in the NMR proton spectrum. The step 12 of performing the magnetic labeling can also include, but is not required for the purposes of performing this method, selectively irradiating and saturating one or more of the non-exchangeable protons for a particular compound over a predetermined frequency range and selectively exciting one or more of the non-exchangeable protons for a particular compound over the predetermined frequency range. Selectively exciting the protons can also further include pulsed radiofrequency (RF) inversion using one or more RF pulses. In addition, the method can encompass a pulsed steady state MRI sequence containing a short saturation RF pulse followed by a small flip angle excitation pulse and brief spatial encoding of one or more spatial frequencies to selectively irradiate and saturate one or more protons. The pulse sequence parameters can be chosen to sufficiently reduce to a predetermined level the simultaneous occurring effects of MTC contrast to allow visualization of exchange relayed NOE contrast.

As noted above, in the performance of this method 10, illustrated in FIG. 1, the non-exchangeable protons can take the form of at least one of an endogenous or exogenous molecule. Here, the endogenous molecule is defined as one found naturally within the subject, animal, normal volunteer or patient, while an exogenous molecule is defined as one introduced into the subject, animal, normal volunteer or the patient for the purposes of performing the MRI experiment. More particularly, an endogenous molecule can be at least one of the group of the following: tissue molecules containing non-exchangeable aliphatic, olefinic, or aromatic protons, as well as exchangeable protons, and wherein the nonexchangeable protons are in sufficiently close proximity to each other and to the exchangeable protons allow intramolecular NOEs to occur during the steady state. These tissue molecules can further take the form of proteins, peptides, sugars, cells. interstitial space, body fluids, or metabolites.

An exogenous molecule, used in the method 10, illustrated in FIG. 1, can be at least one of the group of a contrast agent containing non-exchangeable aliphatic, olefinic, and aromatic protons and exchangeable protons in sufficiently close proximity to allow intramolecular NOEs to occur during the steady state. More particularly, the contrast agent can take the form of at least one of a peptide, sugar, small organic compound, small inorganic compound, organic polymer, inorganic polymer, inorganic complexes, or any other mobile species that can be administered in vivo or in vitro. Additionally the protons can also take the form of one or more of the following types of protons: aliphatic, olefinic, and aromatic protons that can resonate at multiple proton frequencies. The protons are required to have a sufficiently long transverse relaxation time T₂ on the order of milliseconds or longer to generate resonances of finite linewidth in the NMR proton spectrum. These descriptions of the characteristics of the protons are given simply as examples and are not meant to be limiting. Any proton known to one of skill in the art and suitable for the method described herein could be used.

Step 14 of the method 10, illustrated in FIG. 1 includes waiting for intramolecular nuclear overhauser enhancement (NOE) effects to occur between the non-exchangeable proton types as well as between the non-exchangeable protons and exchangeable protons in the same molecule during a magnetic steady state. Indeed, the selective irradiation and saturation in mobile solute molecules induces a magnetic steady state, such that the intramolecular NOEs occur. Additionally, the contrast agents discussed above can be configured and/or selected to be in a predetermined mobility range to display exchange-relayed NOE effects for in vitro and in vivo administration. The mobility range of the contrast agent can also be reduced due to binding of the contrast agent or entry into a more viscous environment.

As illustrated in FIG. 1, the method 10 also includes step 16 of monitoring a reduction in the water signal due to the transfer of NOE labels to the water signal in a manner relayed through the exchangeable protons. Monitoring the water reduction over a predetermined range of irradiation frequencies also allows a depiction of the direct water saturation which can allow a determination of the water frequency shifts on a voxel by voxel basis. Also, an effect of the contrast agent on the water signal can also be used to monitor concentration of the contrast agent.

Step 18 of the method 10, illustrated in FIG. 1, also includes performing analysis to produce an image or spectrum of the subject. While the methods of analysis will be discussed in further detail below, briefly, the analysis can for instance include fitting of a frequency-dependent direct water saturation with a Lorentzian line shape and subtracting this from the frequency dependent total saturation spectrum to determine the exchange relayed NOE effect. Monitoring the water saturation can also be used for analysis, especially when done at the appropriate frequency for the protons. An exchange-relayed NOE water signal intensity can also be analyzed to monitor pH based on changes in exchange rate. The image produced as a result of the analysis can be one-dimensional, two-dimensional or three dimensional. In addition, a spectrum can be used for a region of interest.

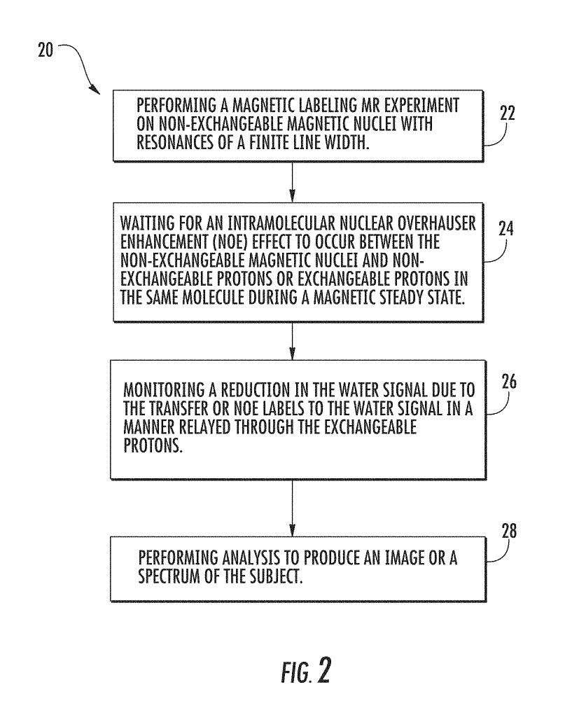

FIG. 2 illustrates another method 20 in accordance with an embodiment of the present invention. Method 20 includes the step 22 of performing a magnetic labeling experiment on non-exchangeable magnetic nuclei with resonances of a finite line width. The magnetic nuclei can take a non-proton form of one of the group of 15N, 13C, 31P, 17O, 23Na. The magnetic nuclei can further include any magnetic nuclei identified in the periodic table. Step 24 includes waiting for an intramolecular nuclear overhauser enhancement (NOE) effect to occur between the non-exchangeable magnetic nuclei and protons in the same molecule during a magnetic steady state. The requirement is that they are sufficiently close to protons in the molecule to allow NOEs to occur that can be further relayed to the water protons in a manner similar to described for protons above. Step 26 includes monitoring a reduction in the water signal due to the transfer of NOE labels to the water signal in a manner relayed through the protons, and step 28 includes also includes performing analysis to produce an image or spectrum of the subject. While the methods of analysis will be discussed in further detail below, briefly, the analysis can for instance include fitting of a frequency-dependent direct water saturation with a Lorentzian line shape and subtracting this from the frequency dependent total saturation spectrum to determine the exchange relayed NOE effect. Monitoring the water saturation or modulation can also be used for analysis, especially when done at the appropriate frequency for the protons. An exchange-relayed NOE water signal intensity can also be analyzed to monitor pH based on changes in exchange rate. The image produced as a result of the analysis can be one-dimensional, two-dimensional or three dimensional. In addition, a spectrum can be used for a region of interest.

With respect to the details regarding the protons and contrast agents that can be used, the discussion above applies to this method 20, as well. The discussion of the method of analysis discussed above with respect to method 10's step 18, also applies to method steps 22-28, as well as the discussion of the method of analysis below. However these methods of analysis are not meant to be limiting, and any analysis method known to one of ordinary skill in the art could be used to analyze and convert the data from the MRI experiment described in method 20 into images.

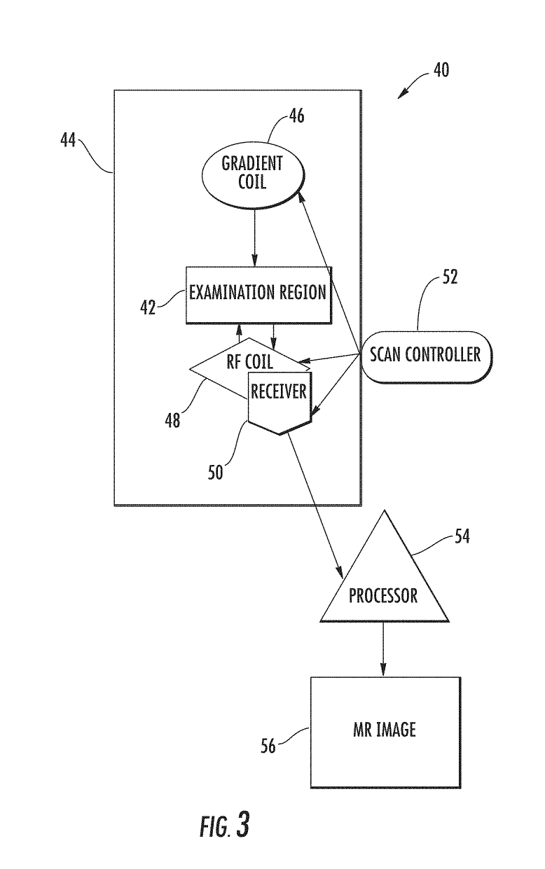

FIG. 3 illustrates a schematic diagram of a MRI system according to an embodiment of the invention. As illustrated in FIG. 3 the MRI system 40 includes an examination region 42 where the patient or the sample to be tested is situated. The examination region 42 is located within a magnet 44 having a bore in which the patient or the sample can be situated. Generally, the magnet 44 takes the form of a persistent superconducting magnet surrounded by cryoshrouding. The magnet 44 produces a magnetic field that extends over the examination region 42. Additionally, magnet 44 can have a strength in the range of approximately 0.5 tesla (T) to 25 T. However, any other known magnet suitable for the creation of a magnetic field that can extend over examination region 42 could also be employed.

A gradient coil 46 is also illustrated in FIG. 3 and is arranged inside the magnet 44 in order to superimpose a magnetic field gradient on the examination region 42. The gradient coil 46 includes coils for producing orthogonal magnetic field gradients, such as gradients in the Cartesian plane (x, y, and/or z gradients). Additionally, one or more radiofrequency (RF) coils 48 are disposed within the gradient coil 46 to apply RF pulses over the examination region 42 and to measure magnetic resonance signals from this region. In fact, the RF coils can be treated as an RF generator to deliver pulses and as a receiver to receive MR signals from the sample or the subject. Alternately, a separate receiver coil 50 consisting of one or more elements can be used to receive the MR signal. Here, the RF transmit coil system 48 is configured to induce RF pulses to the examination region to saturate non-exchangeable magnetic nuclei with resonances of a finite linewidth in the sample or subject. This process invokes a magnetization transfer, such that an intramolecular NOE effect occurs between the non-exchangeable magnetic nuclei and non-exchangeable and exchangeable protons in the same molecule during a magnetic steady state, the effect of which can be relayed to the water protons via said exchangeable protons. A scan controller 52 is used to control the gradient coil 46 and the RF transmit/receive coil system 48, 50 to perform this process.

Data received by the scanner system can then be transmitted to the processor 54 also illustrated in FIG. 3. The processor 54 is configured to receive data from the receiver, wherein the processor is further programmed to convert the data into a magnetic resonance image or spectrum 56. The analysis performed by processor 54 is described in further detail below.

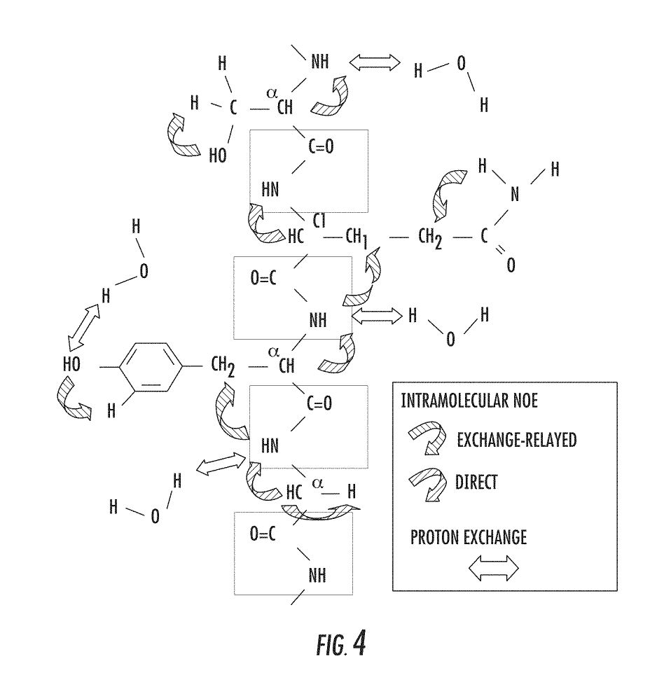

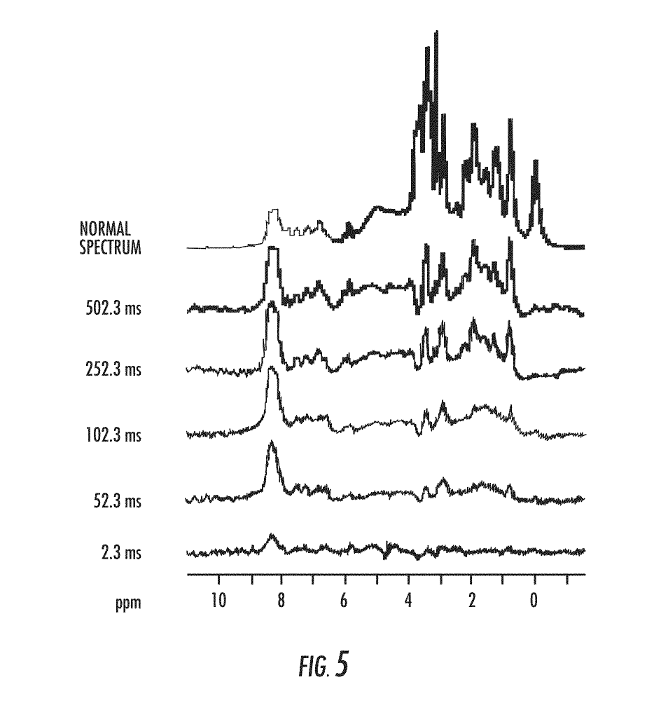

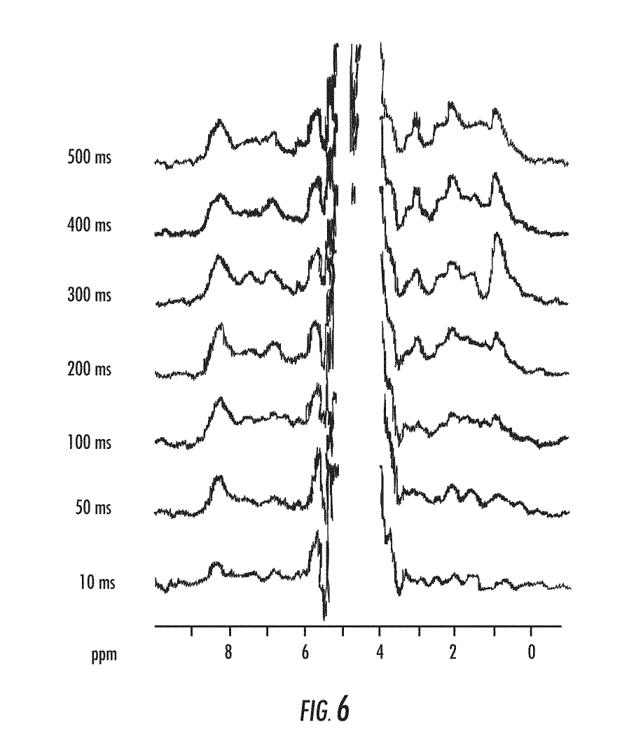

In order to get a better understanding of the competing MT processes in mobile macromolecules (i.e. as reflected in T₂ relaxation times that cause finite linewidths at the appropriate NMR frequency) in solution, it is possible to study the inverse effect through direct magnetic labeling of water molecules using saturation or inversion and to measure the effect on the proton spectrum as a function of time. This so-called Water-Exchange filter (WEX) experiment designed by us has been done for macromolecules in solution as well as on perfused cancer cells and in vivo in the brain. FIG. 4 shows the transfer mechanisms that are active after inversion labeling of water. FIG. 4 also illustrates possible pathways in a mobile protein during the WEX experiment, consisting of selective magnetic labeling of bulk water followed by a waiting period. Further, these inverse processes in FIG. 4 illustrate the occurrence of chemical exchange and cross relaxation, where the cross relaxation occurs either after exchange relay or via direct excitation of protons in the mobile molecule. Such pathways can be detected in cancer cells, as illustrated in FIG. 5 as well as rat brain, as illustrated in FIG. 6.

In addition to exchange-relayed intramolecular NOEs, in which inversion is transferred from water to the molecule through exchangeable groups (mainly OH and NH₂, but also NH) and subsequently to the backbone aliphatic protons, a second cross-relaxation effect (direct intramolecular NOE) occurs because of simultaneous inversion of the C(α)-H protons that resonate close to the water frequency. The exchange-relayed NOEs and intramolecular NOEs build up slower than the direct proton chemical exchange, which is illustrated for perfused cancer cells in FIG. 5, where the NH proton intensities at 8.3 ppm, which corresponds to about +3.5 ppm in a CEST spectrum, increase rapidly with time, followed by a slower rise of the aliphatic signals. In this example for proteins, the sign of the NOE effects is the same as for the exchange effects (in-phase), which is typical for intramolecular NOE effects in larger macromolecules in the slower rotational correlation time limit of the extreme narrowing regime. FIG. 6 illustrates a similar effect in the brain, reflecting the presence of mobile macromolecules for which the proton transverse relaxation times are sufficiently long to allow observation in the NMR spectrum. In MTC and CEST experiments, where saturation is transferred to water, the opposite processes are involved. For mobile macromolecules or other molecules in the appropriate motional range this would lead to exchange-relayed transfer of saturation from the aliphatic protons to water.

FIG. 7 illustrates that, in principle, intermolecular NOEs between bound water molecules and the solutes could also occur, but, for mobile macromolecules, these generally occur on a time scale much slower than exchange-relayed NOEs. For MTC studies, on the contrary, the motional limit is very slow, allowing extremely efficient intermolecular NOE transfer with bound water, which may occur together with exchange-relayed transfer. Here, the exact proportions of these contributions are still under debate. Within the semi-solid proton lattice itself, which is characterized by a transverse relaxation time on the order of microseconds but a longitudinal relaxation time on the order of hundreds of milliseconds, all saturation is efficiently transferred through spin diffusion (fast through-space intramolecular dipolar transfer), which can subsequently be transferred to water though the mentioned processes. The results described below show that MTC effects can be minimized, indicating that these are mainly intermolecular NOEs and not exchange-relayed, while the exchange-relayed intramolecular NOEs of solutes remain.

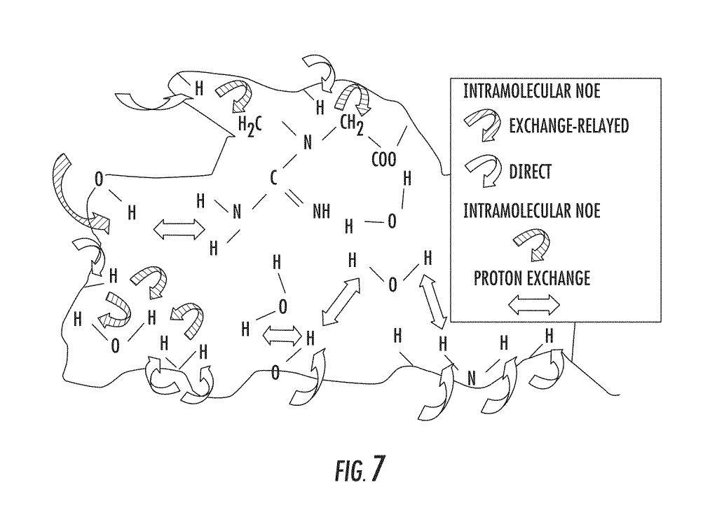

When performing MR saturation experiments as a function of frequency, multiple effects occur, which can be visualized in a so-called Z-spectrum, in which the water saturation is plotted as a ratio for remaining signal after saturation (Sₛₐₜ) with respect to the full water signal without saturation (S₀). The principle of this approach is illustrated in FIGS. 8-10 for CEST imaging in a simulated solution environment. Exchangeable solute protons (s) that resonate at a frequency different from the bulk water protons (w) are selectively saturated using RF irradiation. This saturation is subsequently transferred to bulk water when solute protons exchange with water protons (exchange rate k_{sw}) and the water signal becomes slightly saturated. In view of the low concentration of solute protons (μM to mM range), a single transfer of saturation would be insufficient to show any discernable effect on water protons, the concentration of which is about 110 M. However, because the water pool is much larger than the saturated solute proton pool, each exchanging saturated solute proton is replaced by a non-saturated water proton, which is then again saturated.

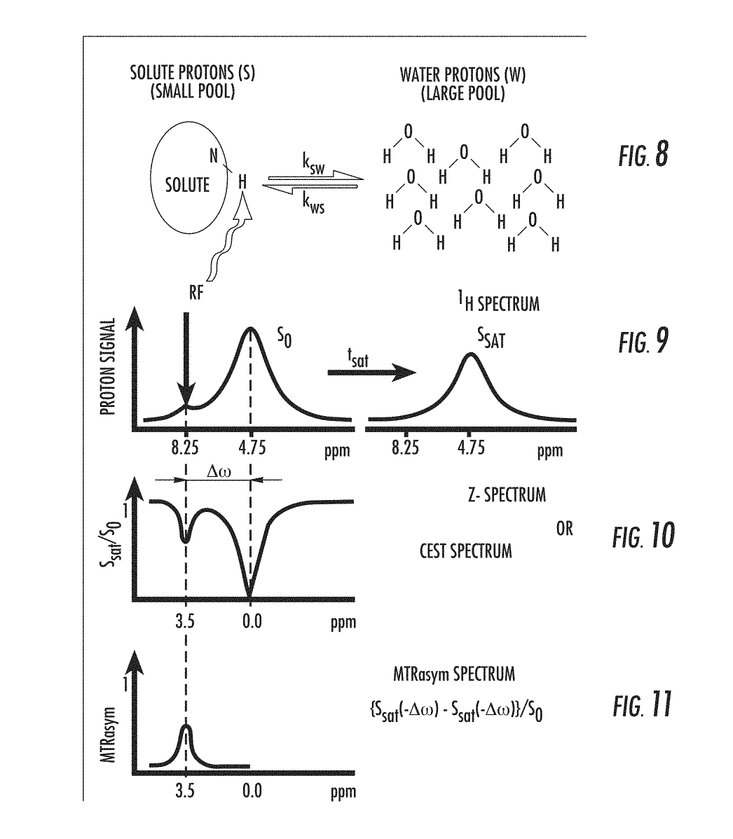

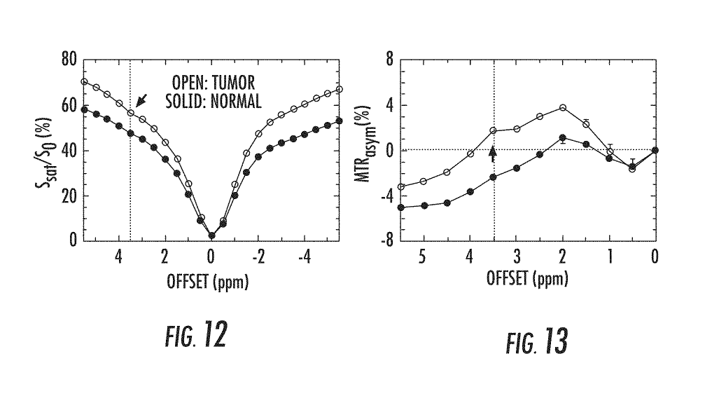

If the solute protons have a sufficiently fast exchange rate (ms range) and the saturation time (tₛₐₜ) is sufficiently long (s range), prolonged irradiation leads to substantial enhancement of this saturation effect, which eventually becomes visible on the water signal, as illustrated in FIG. 9, allowing such low concentration solutes to be imaged. These frequency dependent saturation effects are visualized similar to conventional MTC spectra by plotting Sₛₐₜ/S₀ as a function of saturation frequency, as illustrated in FIG. 10. This gives what has been dubbed a Z-spectrum or CEST-spectrum. Such a spectrum is characterized by the symmetric direct saturation (DS) around the water frequency, which has led to assignment of 0 ppm to the water frequency, a feature often confusing to basic NMR spectroscopists. This direct saturation may interfere with detection of CEST effects, which is addressed by employing the symmetry of the DS through a so-called MTR asymmetry analysis with respect to the water frequency, as illustrated in FIG. 11. Such an analysis inherently assumes independent contributions of solute and water protons, which need not be the case as we will see below, but it has worked well in first approximation for many applications.

This process is characterized by subtracting right (−Δω) and left (Δω) signal intensity ratios through:

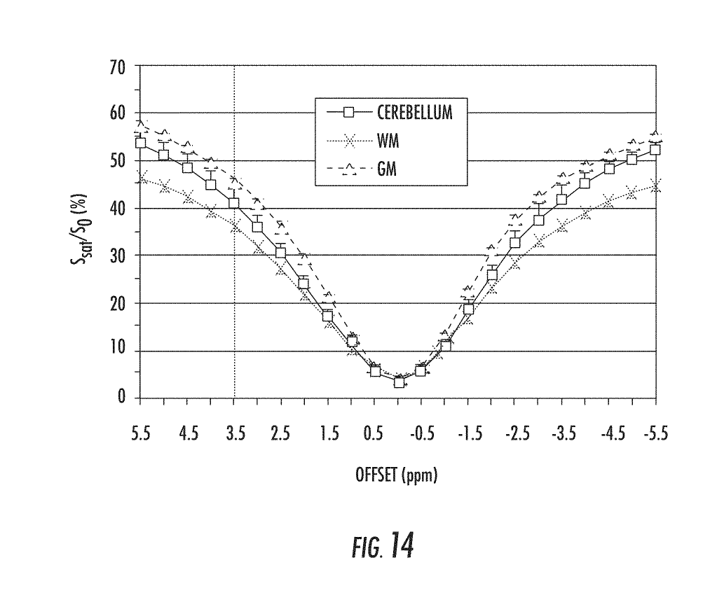

MTR_{asym}(Δω)=MTR(Δω)−MTR(−Δω)=Sₛₐₜ(−Δω)/S₀−Sₛₐₜ(Δω)/S₀ [1]

in which Δω is the frequency difference with water. Similar to MTC imaging, it has to be realized that this type of quantification is often difficult to reproduce between laboratories because, unless saturation efficiency is 100%, the effect depends on the radiofrequency power level (B₁). This can be somewhat ameliorated by taking left/right ratios of the signal attenuation instead of differences, but doing this complicates quantification in terms of exchange rates and concentrations. Asymmetry analysis also is based on an inherent assumption of symmetry of non-CEST contributions around the water signal, which often is not true, especially in vivo but also in vitro. FIGS. 8-11 explain the CEST without interference of competing transfer mechanisms. In tissue, in addition to direct water saturation, multiple magnetization transfer mechanisms may contribute to the CEST spectrum, especially conventional MTC effects, which may be as large as 20-60%, depending on the B1 field used. The solid-like protons detected in MTC have a very short T₂ (and T₂*) and, therefore, resonate over a very large spectral width in a range of approximately ±100 kHz, as illustrated in FIG. 12 where much signal loss is still visible at 5 ppm, known to extend far beyond this range. This does not allow selective RF irradiation of individual resonances in the solid matrix. In contrast, the frequency offset in CEST experiments is limited to a small range around the water resonance, as illustrated in FIG. 13.

CEST effects are generally clearly asymmetric with respect to the water frequency, while MT effects look symmetric, as illustrated in FIGS. 12 and 13, which has been used to separate CEST from MTC and DS through MTR asymmetry analysis, which allows detection of small amide proton transfer (APT) effects from mobile tissue proteins/peptides, as illustrated in FIG. 13. Unfortunately MT effects are not totally symmetric hampering CEST analysis in vivo. This is illustrated in FIGS. 12 and 13 for a 9L glioma model in rat brain. In addition to this, the literature has mostly ignored the fact that intramolecular NOE effects occur and can interfere through the mechanism described above, namely relayed through exchange.

If such NOEs occur, they will reduce the apparent CEST effect measured by asymmetry analysis. To avoid such complications and to allow the separate assessment of exchange-relayed intramolecular NOE and CEST effects in vivo with minimal interference of MTC effects, a pulse sequence was designed that accomplishes the build-up of a magnetization steady state in which the effects of competing solid-like magnetization transfer effects are very small so that the exchange-relayed effects of non-exchangeable protons as well as CEST effects can be directly visualized. It also requires a procedure for analyzing saturation spectra without the need for using so-called asymmetry analyses that is current state of the art for assessing chemical exchange saturation transfer effect in MRI. This analysis includes a fitting of the direct water saturation using so-called Lorentzian Difference Analysis (LDA).

This LDA consists of selecting a set of points in a narrow range around the water line as well as several points further downfield and/or upheld (about 9-10 ppm or more from the water resonance) and to fit a Lorentzian lineshape. The Lorentzian curve can be used to shift the acquired data to correct for B0 inhomogeneity and to determine CEST/APT and exchange-relayed NOE effects. The CEST/APT and exchange-relayed NOE signals can be quantified without the need to use the up-field side as a control.

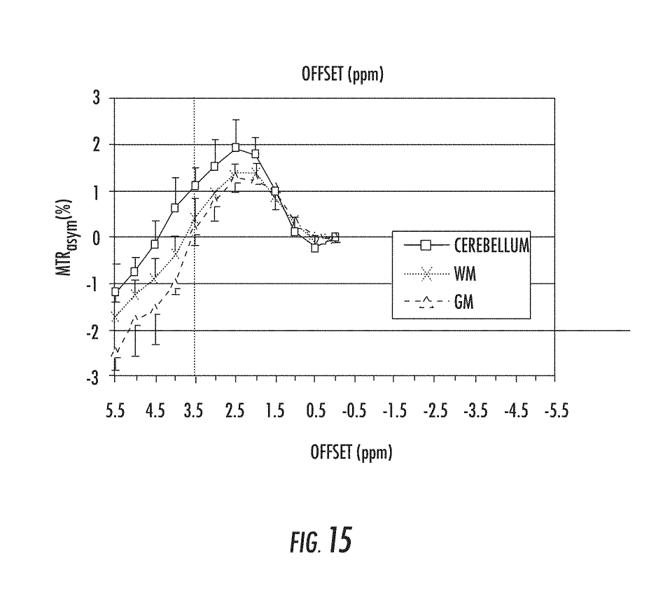

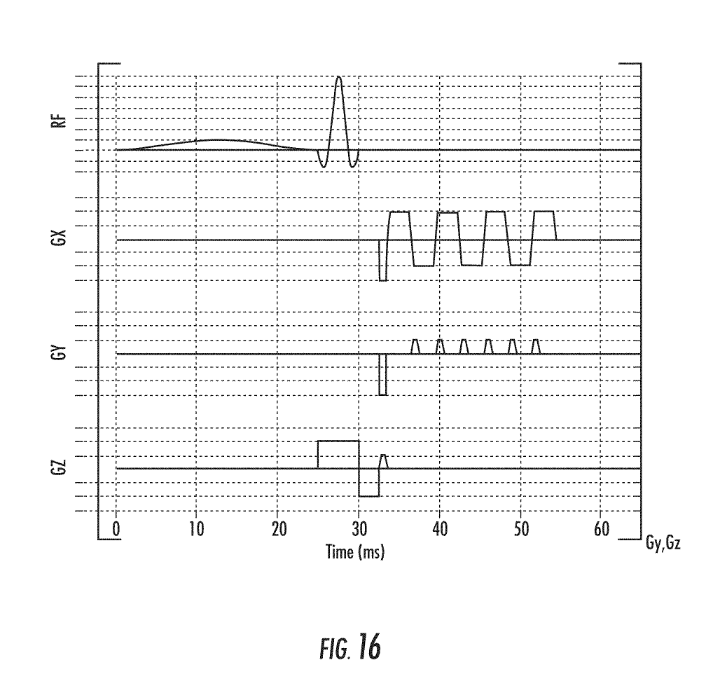

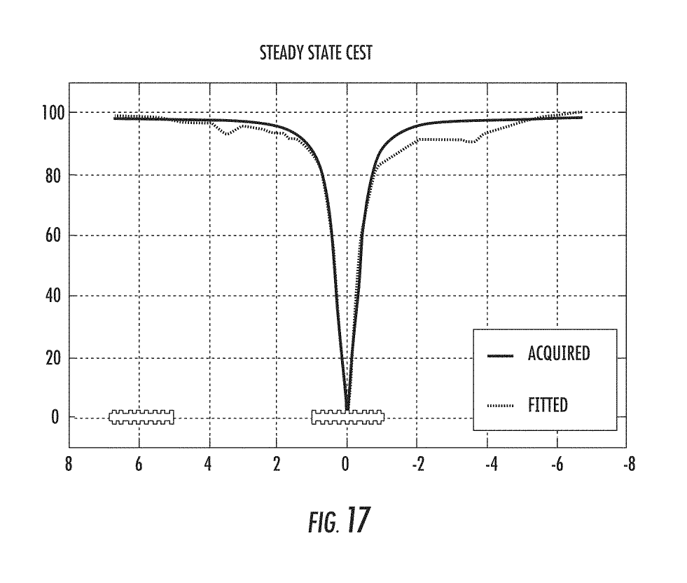

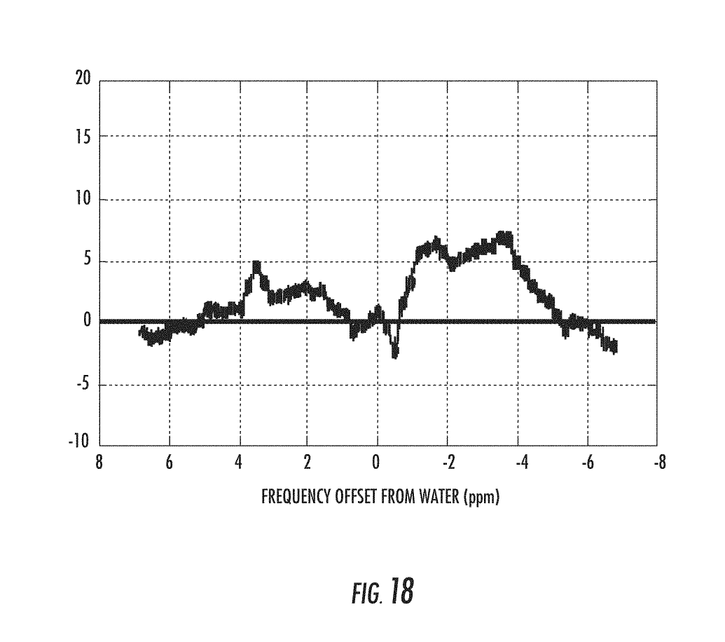

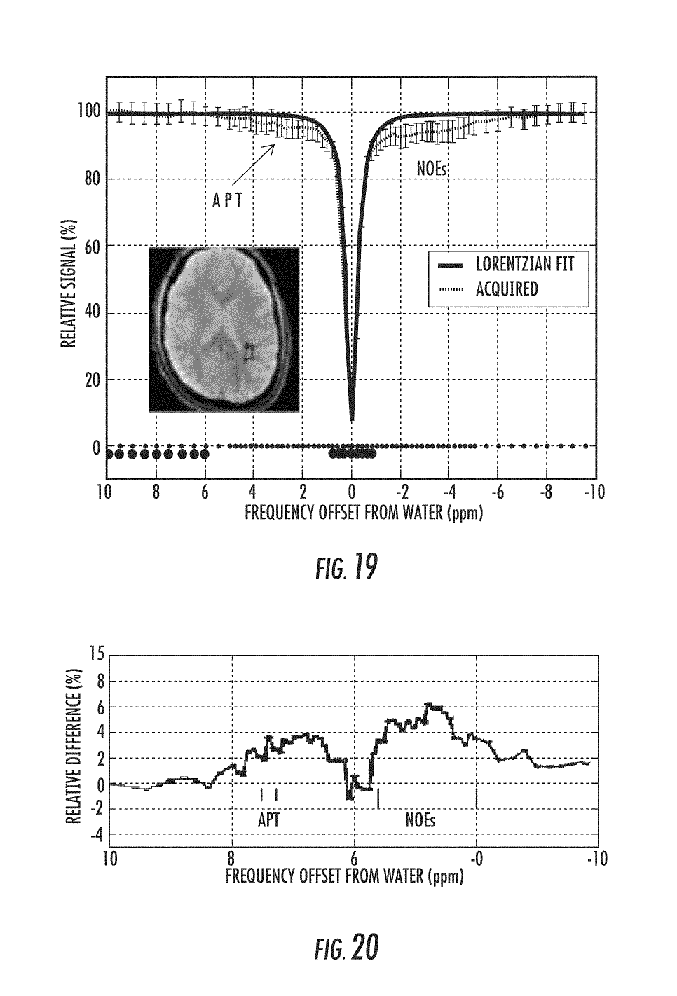

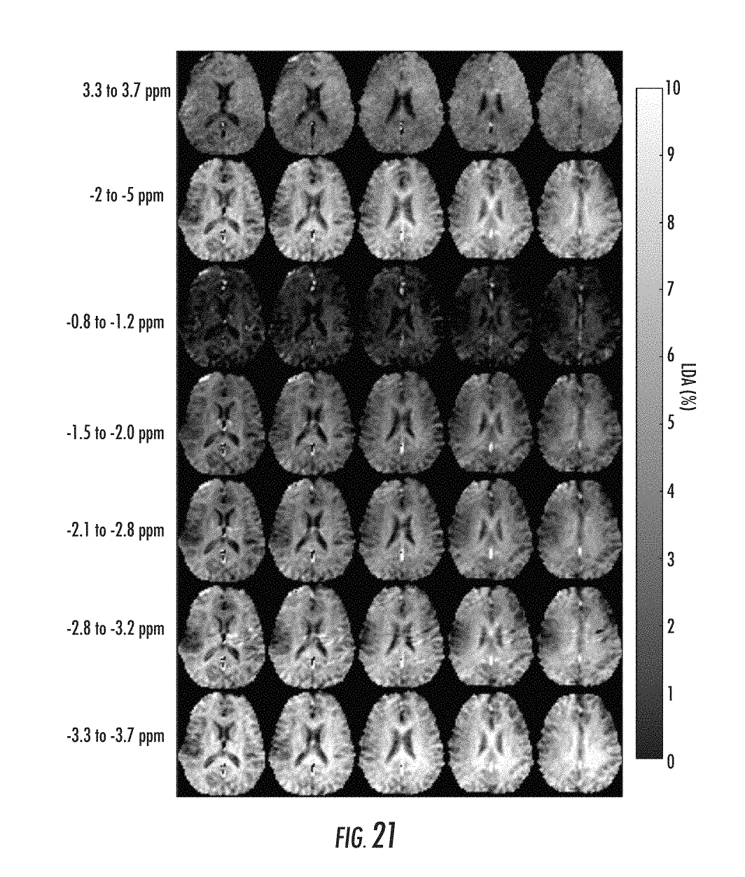

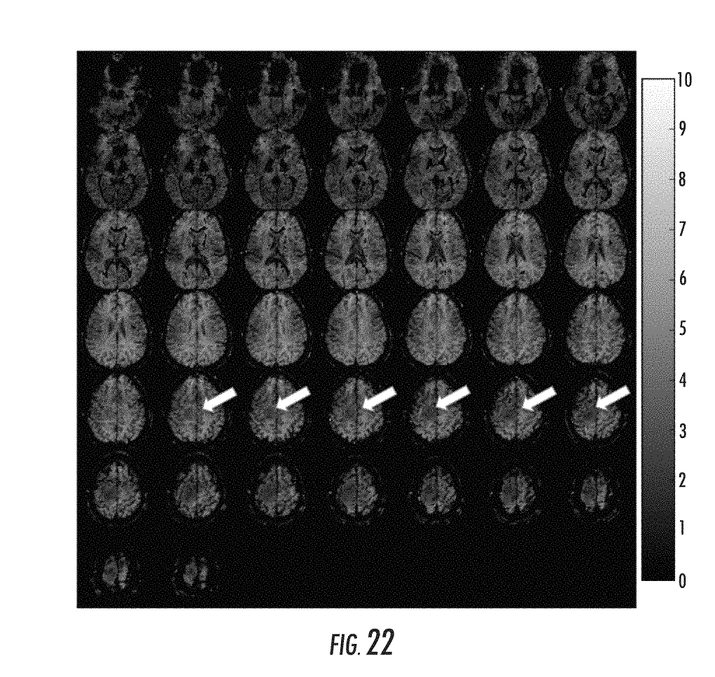

Note that the build-up of saturation and consecutive NOEs and exchange transfer depends on the RF power and, as shown in FIGS. 4-7, timescale of the measurement. At higher power, the intramolecular exchange-relayed NOE effects are expected to be obscured by MTC. For lower power under steady state conditions (longer time scale), the intramolecular NOEs in mobile molecules can build up. Examples of the first condition are given in FIGS. 14-15 for a region of gray and white matter in the cerebrum and a region in the cerebellum in human brain at 3 Tesla. When using conventional CEST RF field and timing settings, namely a saturation time (tsat) of 4×200 ms, RF field (B1) of 2 μT and repetition time (TR) of 2.5 sec, there is a large (40-60%) MTC effect and limited visibility of possible NOEs in the aliphatic (−0.5 to −5 ppm) frequency range (FIG. 14 and FIG. 15). On the other hand, when performing a low-power short-RF pulse steady state 3D approach, MTC effects are strongly reduced. One possible pulse sequence to achieve this is exemplified in FIG. 16, with short saturation pulses (tsat=25 ms) and B1=1.0 μT and TR=65 ms and flip angle optimized for the TR (Ernst angle). Using this sequence on the same human volunteer, the exchange-relayed (ER) NOEs and CEST signals become visible (FIGS. 17, 18) while the MTC effects are minimized. Notice that the ER-NOE experiments will require the use of short tₛₐₜ (generally below 100 ms) and RF field B1 (generally less than 2 μT), but that the experimental requirement varies with transmit coil setup (size and thus B1 transmit efficiency) and magnetic field (T₁ difference). For each field and coil setup the experiment needs to be experimentally optimized at least once by varying tsat, B1 and TR to minimize the MTC contribution and maximize the ER-NOE for the organ or sample of interest. Using these steady state parameters the conventional asymmetry analysis used for CEST analysis would be wrong because NOE effects partially compensate or overwhelm the NH effects. However, this asymmetry analysis is no longer needed because the steady-state approach has limited MTC effect and a narrow direct saturation profile at the water resonance. As a consequence, this procedure allows us to evaluate both CEST and NOE effects, as illustrated in FIGS. 17 and 18. FIG. 19 illustrates a Z-spectrum in a region of white matter obtained from a 3D steady-state whole-brain acquisition (40 slices) at 7 Tesla. The isolated NOE and APT effects obtained after LDA analysis are also shown in FIG. 20. In addition, images are shown in FIG. 21 for the ER-NOE effects (integral of signals between −2 ppm and −5 ppm) of multiple slices throughout the brain based on such Z-spectra.

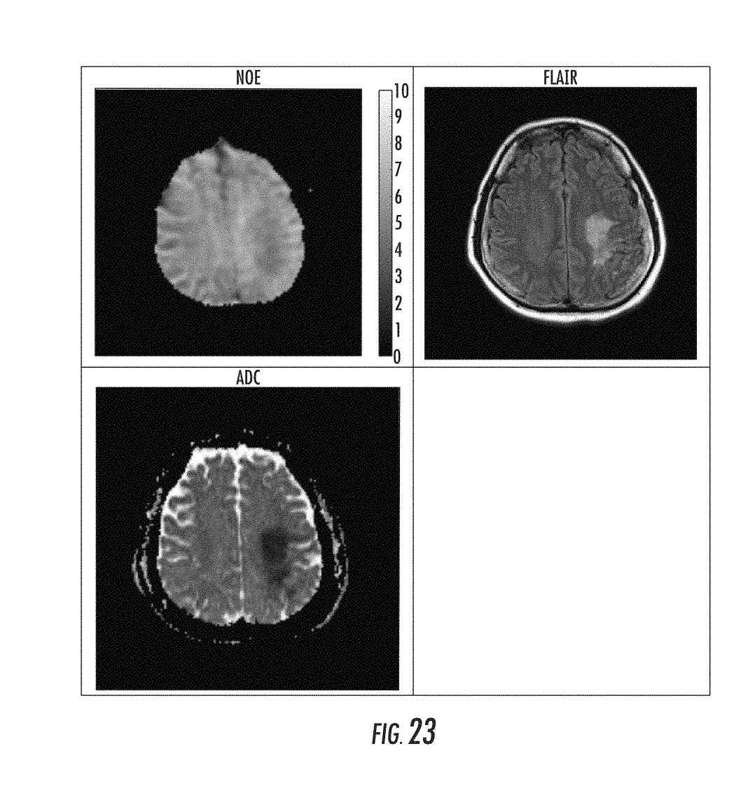

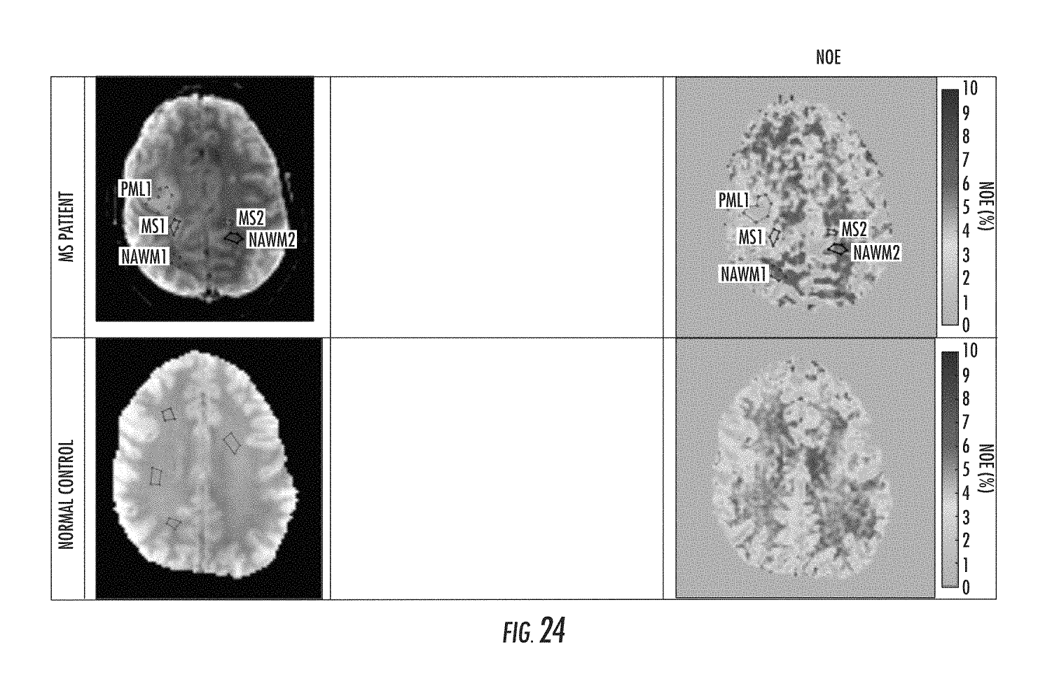

This method can be applied to a number of clinical and diagnostic applications. One of these is to assess the effects of pH during ischemia or other pathologies in which pH is affected, as reflected in a change in the rate of the exchange-relayed process that is used to visualize the intramolecular NOE effects. Another is to visualize changes in concentration in any of the endogenous compounds that contribute to such NOE effects in pathologies such as cancer, neurodegeneration (Alzheimer's disease, Huntington's disease, multiple sclerosis, etc.), diabetes, inflammation, etc. The methodology can detect changes in tissue properties for both endogenous and exogenous compounds, including but not limited to pH changes, concentration changes, and changes in mobility (e.g. upon binding). Applications encompass clinical areas related to disease detection, staging, and monitoring of treatment as well as detection of molecular markers and specific cells (e.g. stem cells) for molecular and cellular imaging. These examples are not meant to be limiting and this method could be applied to any number of diagnostic areas. FIG. 22 shows an image for the ER-NOE effects (integral of signals between −2 ppm and −5 ppm) from a brain tumor study. The white arrows point at the decreased signal in the tumor. FIG. 23 shows the ER-NOE effects from a stroke study showing a decrease in the stroke area. FIG. 24 shows an image of a brain (top left), and NOE map (top right) from patient with multiple sclerosis compared to a control brain (bottom). Notice the great reduction in NOE signal in the lesions in the patient.

The many features and advantages of the invention are apparent from the detailed specification, and thus, it is intended by the appended claims to cover all such features and advantages of the invention, which fall within the true spirit and scope of the invention. Further, since numerous modifications and variations will readily occur to those skilled in the art, it is not desired to limit the invention to the exact construction and operation illustrated and described, and accordingly, all suitable modifications and equivalents may be resorted to, falling within the scope of the invention.

Although the present invention has been described in connection with preferred embodiments thereof, it will be appreciated by those skilled in the art that additions, deletions, modifications, and substitutions not specifically described may be made without departing from the spirit and scope of the invention as defined in the appended claims.

What is claimed is:

1. A method for obtaining a magnetic resonance (MR) image or spectrum, comprising:
performing a magnetic labeling MRI experiment on non-exchangeable protons of molecules with resonances of finite linewidth in the MR proton spectrum;
waiting for intramolecular nuclear overhauser enhancement (NOE) effects to occur between the non-exchangeable protons types as well as between nonexchangeable and exchangeable protons in the same molecule during a magnetic steady state;
monitoring a reduction in a water signal due to a transfer of NOE labels to the water signal in a manner relayed through the exchangeable protons; and,
performing analysis to produce an image or spectrum of the subject or sample.

2. The method according to claim 1, wherein the non-exchangeable protons consist of one of the group of aliphatic, olefinic, and aromatic protons.

3. The method according to claim 1, wherein the non-exchangeable protons are those present in of one of the group of endogenous and exogenous molecules.

4. The method according to claim 1, further comprising the protons having a transverse relaxation time T₂ in the millisecond or longer range, allowing such protons to have finite linewidth in the proton spectrum.

5. The method according to claim 1 wherein performing magnetic labeling comprises:
selectively irradiating and saturating one or more of the non-exchangeable protons for a particular compound over a predetermined frequency range and inducing a modulation or change of the longitudinal magnetization from equilibium; and
selectively exciting one or more of the non-exchangeable protons for a particular compound over the predetermined frequency range and inducing a modulation or change of the longitudinal magnetization from equilibium.

6. The method according to claim 5 wherein selectively exciting comprises pulsed radiofrequency (RF) inversion using one or more RF pulses.

7. The method of claim 5 wherein selectively irradiating and saturating further comprises inducing a magnetic steady state such that intramolecular NOEs occur in mobile solute molecules.

8. The method of claim 3 wherein the endogenous molecules consist of one of the group of: tissue molecules containing both non-exchangeable protons and exchangeable protons, and wherein the non-exchangeable protons are in sufficiently close proximity to exchangeable protons allow intramolecular NOEs to occur during the steady state.

9. The method of claim 8 wherein the tissue molecules consist of one of the group of proteins, peptides, sugars, metabolites.

10. The method of claim 3, wherein exogenous molecules consist of one of the group of a contrast agents containing both non-exchangeable protons and exchangeable protons in sufficiently close proximity to allow intramolecular NOEs to occur during the steady state.

11. The method of claim 3, wherein exogenous molecules comprise a contrast agent containing non-exchangeable protons that can bind to molecules containing exchangeable protons that are then in sufficiently close proximity to allow NOEs within the binding complex to occur during the steady state.

12. The method of claim 10 wherein the contrast agent consist of one of the group of peptides, sugars, small organic compounds, small inorganic compounds, organic polymers, inorganic polymers, inorganic complexes, and other mobile species that can be administered in vivo.

13. The method of claim 12 further comprising the contrast agent being configured to be in a predetermined mobility range to display exchange-relayed NOE effects for one of the groups consisting of in vivo or in vitro.

14. The method of claim 13 comprising reducing mobility with one of the group consisting of binding the agent or entering a more viscous environment.

15. The method of claim 1 further comprising using a pulsed steady state MRI sequence containing a short saturation RF pulse followed by a small flip angle excitation pulse and brief spatial encoding of one or more spatial frequencies to selectively irradiate and saturate one or more non-exchangeable protons and waiting for NOEs to occur.

16. The method of claim 15 further comprising choosing the pulse sequence parameters to sufficiently reduce the simultaneously occurring effects of MTC contrast to allow visualization of the exchange-relayed NOE contrast.

17. The method of claim 1 further comprising monitoring of the water reduction over a predetermined range of frequencies to allow depiction of a direct water saturation.

18. The method of claim 17 further comprising using the monitoring of the direct water saturation to allow a determination of the water frequency shifts on a voxel by voxel basis.

19. The method of claim 1 wherein the step of performing analysis further comprises fitting with a Lorentzian lineshape using a subset of frequencies based on frequency-dependent direct water saturation and subtracting this from the frequency dependent total saturation spectrum to determine an exchange-relayed NOE effect.

20. The method of claim 1 wherein the step of performing analysis further comprises monitoring a water saturation at an appropriate frequency for the protons.

21. The method of claim 12 further comprising using multiple contrast agents containing of one of the group of aliphatic, olefinic, and aromatic protons to have multiple proton frequencies.

22. The method of claim 1 further comprising using an exchange-relayed NOE water signal intensity to monitor pH based on changes in exchange rate with pH.

23. The method of claim 11 further comprising using an effect on the water signal of the contrast agents to monitor concentration of the agent or of cells containing the agent.

24. The method of claim 1 further comprising using the effect of the water signal to monitor one of the group consisting of binding and reaction kinetics.

25. The method of claim 1 further comprising using ER-NOE agents to monitor one of the group consisting of cell delivery in the vesicles and drug delivery in the vesicles.

26. The method of claim 1 wherein an image consists of one of the group of one-dimensional, two-dimensional or three-dimensional.

27. The method of claim 8 wherein tissue consists of one of the group of cells, interstitial space or body fluids.

28. The method of claim 1 wherein the resonance frequency range of the protons with finite linewidth in diamagnetic compounds is in a range of approximately 10-12 ppm around the water proton frequency.

29. The method of claim 1 wherein the resonance frequency range of the protons with finite linewidth in paramagnetic compounds may be anywhere in a range of ±100 ppm around the water proton resonance.

30. The method of claim 1 wherein the step of performing analysis further comprises fitting of the z-spectrum using a model of the mobile macromolecular and water proton pools with or without MTC contributions, for instance but not limited to using the Bloch Equations.

31. A method for obtaining a magnetic resonance (MR) image or spectrum comprising:
performing a magnetic labeling MRI experiment on non-exchangeable magnetic nuclei with resonances of a finite line width;
waiting for an intramolecular nuclear overhauser enhancement (NOE) effect to occur between the non-exchangeable magnetic nuclei and nonexchangeable protons or between the non-exchangeable magnetic nuclei and exchangeable protons in the same molecule during a magnetic steady state;
monitoring a reduction in the water signal due to the transfer of NOE labels to the water signal in a manner relayed through the exchangeable protons;
performing analysis to produce an image or spectrum of the subject or sample.

32. The method of claim 31, wherein the magnetic nuclei consist of one of the group of 15N, 13C, 31P, 17O, 23Na.

33. The method of claim 31, wherein the magnetic nuclei comprise any of the magnetic nuclei identified in the periodic table.

34. A system for providing a magnetic resonance image of a subject in an examination region during a magnetic resonance imaging session comprising:
a magnet configured to generate a magnetic field in the examination region;
a gradient coil that superimposes a magnetic field gradient on the magnetic field;
an RF coil configured to introduce RF pulses to the examination region to saturate non-exchangeable magnetic nuclei with resonances of a finite line width in the sample and invoke a magnetization transfer, such that an intramolecular nuclear overhauser enhancement (NOE) effect occurs between the non-exchangeable magnetic nuclei and exchangeable magnetic nuclei in the same molecule during a magnetic steady state;
a scan controller which controls the gradient coil and the RF coil to perform the magnetic resonance imaging session;
a receiver configured to receive magnetic resonance signals during the magnetic resonance imaging session; and
a processor configured to receive data from the receiver, wherein the processor is further programmed to convert the magnetic resonance signals into the magnetic resonance image.
